(19) United States
(12) Patent Application Publication
(10) Pub. No.: US 2026/0161851 A1
(43) Pub. Date: Jun. 11, 2026

(54) DESIGN ASSITANCE DEVICE, DESIGN ASSITANCE METHOD, AND DESIGN ASSITANCE PROGRAM

(71) Applicant: Resonac Corporation, Minato-ku, Tokyo (JP)

(72) Inventor: Kyohei HANAOKA, Minato-ku, Tokyo (JP)

(21) Appl. No.: 18/707,918

(22) PCT Filed: Nov. 2, 2022
(86) PCT No.: PCT/JP2022/041089

§ 371 Date: Jun. 7, 2024

(30) Foreign Application Priority Data
Nov. 8, 2021 (JP) 2021-181773

(51) Int. Cl. G06F 30/27

(52) U.S. Cl. CPC G06F 30/27

(57) ABSTRACT

A design assistance device includes a data acquisition unit acquiring performance data consisting of a design parameter group and a measurement value of a measurement item, a model construction unit constructing a predictive model for predicting the measurement value as a probability distribution or the like on the basis of the design parameter group, a sampling unit used for each predictive model to sample a predetermined number of points of a measurement value group, an evaluation value calculation unit scalarizing a vector having each measurement value included in the measurement value group as an element to calculate an evaluation value of each sampling point, an acquisition function evaluation unit outputting an acquisition function evaluation value on the basis of a distribution of the evaluation value of each sampling point, and a design parameter group acquisition unit acquiring the design parameter group by optimization of the acquisition function evaluation value.

### TECHNICAL FIELD

One aspect of the present disclosure relates to a design assistance device, a design assistance method, and a design assistance program.

### BACKGROUND ART

Product design utilizing machine learning has been studied. As one field of the product design, for example, in the design of a functional material, for example, a model for estimating the characteristic of a material by machine learning using learning data consisting of a pair of a raw material compounding ratio and a characteristic relevant to an experimented and produced material is constructed, and a characteristic with respect to an unexperimented raw material compounding ratio is predicted. By creating an experiment plan in accordance with the prediction of the characteristic, it is possible to efficiently optimize a design parameter such as the characteristic of the material and the raw material compounding ratio, and improve a development efficiency. In addition, Bayesian optimization is known to be effective as such an optimization method, and a design device outputting a design value by using the Bayesian optimization is known (for example, refer to Patent Literature 1).

### CITATION LIST

### Patent Literature

Patent Literature 1: Japanese Unexamined Patent Publication No. 2020-52737

### SUMMARY OF INVENTION

### Technical Problem

On the other hand, in the product development of the material or the like, single objective optimization may be performed in order to improve one evaluation value to be calculated by an evaluation function on the basis of measurement values of a plurality of characteristics. In order to optimize one evaluation value and the design parameter, it is considered to directly predict the evaluation value by machine learning using one evaluation value as an object variable. However, there is a possibility that a learning accuracy decreases due to non-linear conversion according to an evaluation function or the like, and there is a problem that an optimization efficiency is degraded. Note that, such problems are not limited to the material design, but common to the general product design.

Therefore, the present invention has been made in consideration of the problems described above, and an object thereof is to enable the optimization of one evaluation value composed of an object variable and a design variable at a few number of experiments and a low load, in a production process of a product, an in-progress product, a half-finished product, a component, or a production prototype.

### Solution to Problem

A design assistance device according to one aspect of the present disclosure is a design assistance device obtaining a plurality of design parameters, in which one evaluation value indicating a characteristic of a product, an in-progress product, a half-finished product, a component, or a production prototype is improved, in order to be applied to a method for optimizing a design parameter by repeating determination of the design parameter and production of the product, the in-progress product, the half-finished product, the component, or the production prototype based on the determined design parameter, in design of the product, the in-progress product, the half-finished product, the component, or the production prototype to be produced on the basis of a design parameter group consisting of the plurality of design parameters, the one evaluation value is calculated on the basis of measurement values of a plurality of measurement items, and the design assistance device includes: a data acquisition unit acquiring a plurality of performance data pieces consisting of the design parameter group and the measurement value of each of the plurality of measurement items, relevant to the produced product, in-progress product, half-finished product, component, or production prototype; a model construction unit constructing, on the basis of the performance data, a predictive model for predicting the measurement value of the measurement item as a probability distribution or an approximate or alternative index thereof on the basis of the design parameter group; a sampling unit sampling a predetermined number of points of a measurement value group, with the measurement value group consisting of a plurality of measurement values sampled from a multidimensional probability distribution of the measurement value obtained from each predictive model as one sampling point; an evaluation value calculation unit scalarizing a vector having the number of measurement values included in the measurement value group as a dimension number and a value of each measurement value as an element by predetermined arithmetic to calculate an evaluation value of the measurement value group of each sampling point; an acquisition function evaluation unit outputting an acquisition function evaluation value relevant to the improvement of the evaluation value by a predetermined acquisition function, with the design parameter group as input, on the basis of a distribution of the evaluation value of each sampling point; a design parameter group acquisition unit acquiring at least one design parameter group by optimization of the acquisition function evaluation value; and an output unit outputting the design parameter group acquired by the design parameter group acquisition unit.

A design assistance method according to one aspect of the present disclosure is a design assistance method of a design assistance device obtaining a plurality of design parameters, in which one evaluation value indicating a characteristic of a product, an in-progress product, a half-finished product, a component, or a production prototype is improved, in order to be applied to a method for optimizing a design parameter by repeating determination of the design parameter and production of the product, the in-progress product, the half-finished product, the component, or the production prototype based on the determined design parameter, in design of the product, the in-progress product, the half-finished product, the component, or the production prototype to be produced on the basis of a design parameter group consisting of the plurality of design parameters, the one evaluation value is calculated on the basis of measurement values of a plurality of measurement items, and the design assistance method includes: a data acquisition step of acquiring a plurality of performance data pieces consisting of the design parameter group and the measurement value of each of the plurality of measurement items, relevant to the produced product, in-progress product, half-finished product, component, or production prototype; a model construction step of constructing, on the basis of the performance data, a predictive model for predicting the measurement value of the measurement item as a probability distribution or an approximate or alternative index thereof on the basis of the design parameter group; a sampling step of sampling a predetermined number of points of a measurement value group, with the measurement value group consisting of a plurality of measurement values sampled from a multidimensional probability distribution of the measurement value obtained from each predictive model as one sampling point; an evaluation value calculation step of scalarizing a vector having the number of measurement values included in the measurement value group as a dimension number and a value of each measurement value as an element by predetermined arithmetic to calculate an evaluation value of the measurement value group of each sampling point; an acquisition function evaluation step of outputting an acquisition function evaluation value relevant to the improvement of the evaluation value by a predetermined acquisition function, with the design parameter group as input, on the basis of a distribution of the evaluation value of each sampling point; a design parameter group acquisition step of acquiring at least one design parameter group by optimization of the acquisition function evaluation value; and an output step of outputting the design parameter group acquired in the design parameter group acquisition step.

A design assistance program according to one aspect of the present disclosure is a design assistance program for allowing a computer to function as a design assistance device obtaining a plurality of design parameters, in which one evaluation value indicating a characteristic of a product, an in-progress product, a half-finished product, a component, or a production prototype is improved, in order to be applied to a method for optimizing a design parameter by repeating determination of the design parameter and production of the product, the in-progress product, the half-finished product, the component, or the production prototype based on the determined design parameter, in design of the product, the in-progress product, the half-finished product, the component, or the production prototype to be produced on the basis of a design parameter group consisting of the plurality of design parameters, the one evaluation value is calculated on the basis of measurement values of a plurality of measurement items, and the design assistance program attains: a data acquisition function of acquiring a plurality of performance data pieces consisting of the design parameter group and the measurement value of each of the plurality of measurement items, relevant to the produced product, in-progress product, half-finished product, component, or production prototype; a model construction function of constructing, on the basis of the performance data, a predictive model for predicting the measurement value of the measurement item as a probability distribution or an approximate or alternative index thereof on the basis of the design parameter group; a sampling function of sampling a predetermined number of points of a measurement value group, with the measurement value group consisting of a plurality of measurement values sampled from a multidimensional probability distribution of the measurement value obtained from each predictive model as one sampling point; an evaluation value calculation function of scalarizing a vector having the number of measurement values included in the measurement value group as a dimension number and a value of each measurement value as an element by predetermined arithmetic to calculate an evaluation value of the measurement value group of each sampling point; an acquisition function evaluation function of outputting an acquisition function evaluation value relevant to the improvement of the evaluation value by a predetermined acquisition function, with the design parameter group as input, on the basis of a distribution of the evaluation value of each sampling point; a design parameter group acquisition function of acquiring at least one design parameter group by optimization of the acquisition function evaluation value; and an output function of outputting the design parameter group acquired by the design parameter group acquisition function.

According to such an aspect, the predictive model for predicting the measurement values of the plurality of measurement items for the calculation and the evaluation of the evaluation value is constructed for each measurement item on the basis of the performance data. Since such a predictive model predicts the measurement value of the measurement item as the probability distribution or the approximate or alternative index thereof, any number of points of the measurement value group can be sampled on the basis of the multidimensional distribution of the measurement value obtained from the predictive model of each measurement item. By performing arithmetic using a predetermined evaluation formula with respect to the vector having the measurement value group of each sampling point as the element, it is possible to obtain the evaluation value relevant to each sampling point expressed by a scalar value. Then, by optimizing the acquisition function evaluation value output using the predetermined acquisition function, on the basis of the distribution of the evaluation value of each sampling point, it is possible to obtain the design parameter group suitable for the next experiment or the like. Accordingly, it is possible to obtain a more accurate predictive model relevant to the measurement value, compared to a method for constructing the acquisition function by directly learning the evaluation value, and it is possible to reduce the number of experiments since the suitability of the design parameter group to be adopted to an experiment or the like is improved by optimizing the acquisition function evaluation value relevant to the evaluation value of the measurement value group obtained by the predictive model.

In the design assistance device according to another aspect, the evaluation value calculation unit may calculate the evaluation value by a predetermined evaluation formula for performing predetermined arithmetic on the basis of the plurality of measurement values included in the measurement value group.

According to such an aspect, it is possible to calculate and set any evaluation value for evaluating the product or the like to be produced by the evaluation formula.

In the design assistance device according to another aspect, the evaluation value calculation unit may calculate a characteristic value as the evaluation value by a theoretical formula for calculating the characteristic value indicating the characteristic relevant to the product, the in-progress product, the half-finished product, the component, or the production prototype, on the basis of the plurality of measurement values included in the measurement value group.

According to such an aspect, the characteristic value for evaluating the product or the like to be produced is calculated by the theoretical formula for calculating the characteristic value. Then, the calculated characteristic value can be the evaluation value for evaluating the product or the like.

In the design assistance device according to another aspect, when the measurement value sampled by using the predictive model of the measurement item is not included in a given domain of definition relevant to the measurement item, the sampling unit may substitute the sampled measurement value with a predetermined value set in advance for the measurement item.

In the design assistance device of the aspect described above, there is a possibility that the sampled measurement value is a value outside the domain of definition of the measurement item due to the sampling from the probability distribution based on the predictive model. As described above, in a case where the measurement value not included in the domain of definition is sampled, the measurement value is substituted with the predetermined value and included in the measurement value group of the sampling point. Accordingly, the accuracy of the evaluation value to be calculated on the basis of the measurement value group is improved.

In the design assistance device according to another aspect, the acquisition function evaluation unit may output the acquisition function evaluation value by any acquisition function of lower confidence bound (LCB), upper confidence bound (UCB), expected improvement (EI), and probability of improvement (PI).

According to such an aspect, the acquisition function evaluation value suitable for evaluating the design parameter group suitable for the improvement of the evaluation value is output.

In the design assistance device according to another aspect, the design parameter group acquisition unit may acquire one design parameter group for optimizing the acquisition function evaluation value.

According to such an aspect, it is possible to obtain the design parameter group capable of improving the evaluation value relevant to the measurement item.

In the design assistance device according to another aspect, the design parameter group acquisition unit may acquire a plurality of design parameter groups by a predetermined algorithm.

According to such an aspect, it is possible to easily obtain the plurality of design parameter groups to be used in the next experiment.

In the design assistance device according to another aspect, the predictive model may be a regression model or a classification model having the design parameter group as input and the probability distribution of the measurement value as output, and the model construction unit may construct the predictive model by machine learning using the performance data.

According to such an aspect, since the predictive model is constructed as a predetermined regression model or classification model, it is possible to obtain the predictive model capable of acquiring the probability distribution of the measurement value of the measurement item or the approximate or alternative index thereof.

In the design assistance device according to another aspect, the predictive model may be a machine learning model for predicting the probability distribution of the measurement value or the approximate or alternative index thereof by using any one of a posterior distribution of a prediction value based on Bayesian theory, a distribution of a prediction value of a predictor configuring an ensemble, a theoretical formula of a prediction interval and a confidence interval of a regression model, Monte Carlo dropout, and a distribution of predictions of a plurality of predictors constructed in different conditions.

According to such an aspect, the predictive model capable of predicting the probability distribution of the measurement value of the measurement item based on the design parameter group, or the approximate or alternative index thereof is constructed.

### Advantageous Effects of Invention

According to one aspect of the present disclosure, the optimization of one evaluation value composed of the object variable and the design variable is enabled at a few number of experiments and a low load, in the production process of the product, the in-progress product, the half-finished product, the component, or the production prototype.

### BRIEF DESCRIPTION OF DRAWINGS

FIG. 1 is a diagram illustrating an outline of a material design process to which a design assistance device according to an embodiment is applied.

FIG. 2 is a block diagram illustrating an example of a function configuration of the design assistance device according to the embodiment.

FIG. 3 is a hard block diagram of the design assistance device according to the embodiment.

FIG. 4 is a diagram illustrating an example of a design parameter group relevant to a produced material.

FIG. 5 is a diagram illustrating an example of a measurement value relevant to the produced material.

FIG. 6 is a flowchart illustrating an optimization process of an evaluation value and a design parameter in material design.

FIG. 7 is a flowchart illustrating an example of contents of a design assistance method in the design assistance device according to the embodiment.

FIG. 8 is a diagram illustrating a configuration of a design assistance program.

### DESCRIPTION OF EMBODIMENTS

Hereinafter, an embodiment of the present invention will be described in detail with reference to the attached drawings. Note that, in the description of the drawings, the same reference numerals will be applied to the same or equivalent elements, and the repeated description will be omitted.

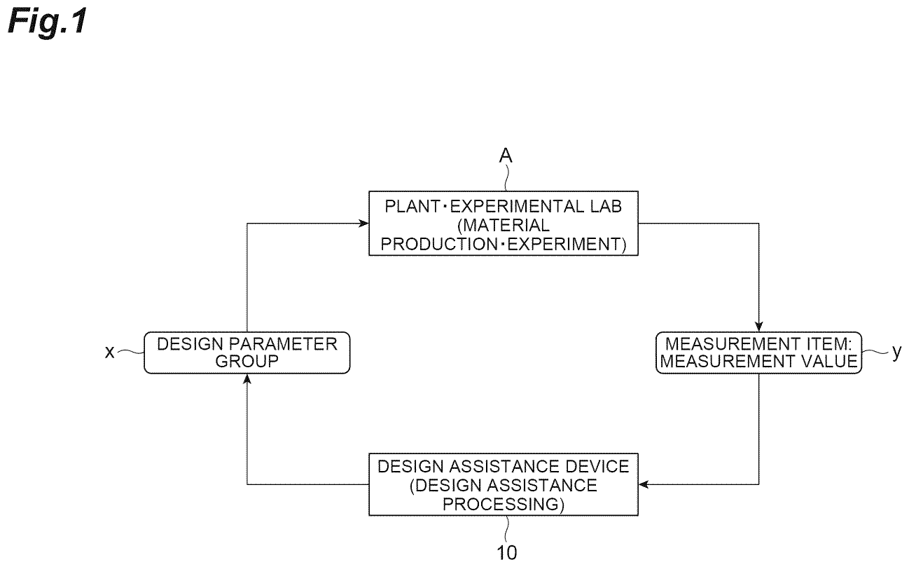

FIG. 1 is a diagram illustrating the outline of a material design process that is an example of a design process of a product, an in-progress product, a half-finished product, a component, or a production prototype to which a design assistance device according to an embodiment is applied. Note that, hereinafter, the “product, the in-progress product, the half-finished product, the component, or the production prototype” will be referred to as the “product or the like”. A design assistance device 10 of this embodiment can be applied to any design process of the product or the like that requires the optimization of one evaluation value indicating the characteristic of the product or the like. The design assistance device 10 can be applied to a method for optimizing a design parameter and an evaluation value of the product or the like by repeating the determination of the design parameter and the production of the product, the in-progress product, the half-finished product, the component, or the production prototype based on the determined design parameter. Specifically, the design assistance device 10 can be applied, for example, to the design of a product such as an automobile and a chemical, the optimization of a molecular structure of the chemical, or the like, in addition to the development and design of a material. In this embodiment, as described above, design assistance processing of the design assistance device 10 will be described by using an example of material design as an example of the design of the product or the like.

As illustrated in FIG. 1, the design assistance processing of the design assistance device 10 is applied to the production and the experiment of a material in a plant and experimental lab A, and the like. That is, the material is produced by a set design parameter group x in the plant and experimental lab A, and the like, and measurement values y of a plurality of measurement items indicating the characteristic of the material are acquired on the basis of the produced material. Note that, the production and the experiment of the material in the plant and experimental lab A may be a simulation. In this case, the design assistance device 10 provides the design parameter group x for the execution of the next simulation.

The design assistance device 10 optimizes one evaluation value and the design parameter on the basis of performance data consisting of the design parameter group x and the measurement values y of the plurality of measurement items of the material produced on the basis of the design parameter group x. Specifically, the design assistance device 10 outputs the design parameter group x for the next production and experiment, in which there is a possibility that a more suitable characteristic is obtained, on the basis of the design parameter group x and the measurement value y relevant to the produced material. One evaluation value is a value to be an index for evaluating the product or the like, and calculated as a scalar value by predetermined arithmetic with respect to a measurement value group consisting of the measurement values of the plurality of measurement items.

The evaluation value may be a value to be calculated by a predetermined evaluation formula for performing predetermined arithmetic on the basis of a plurality of measurement values included in the measurement value group. In such a case, the evaluation formula may be arbitrarily set, and for example, may be uniquely set in accordance with the industry to which the product or the like to be produced belongs, the business for producing the product or the like and the business sector thereof, and the individual involved in the research and development of the product or the like.

In addition, the evaluation value may be a characteristic value indicating the characteristic relevant to the product or the like. In such a case, the evaluation formula may be a theoretical formula for calculating the characteristic value. For example, in a case where the evaluation value of the product or the like is a transmission loss of an electrical signal, the evaluation formula is a formula for multiplying the product of a frequency, the square root of a relative permittivity, and a dielectric dissipation factor by a coefficient.

For example, in the design of a material product, the design assistance device 10 of this embodiment is applied in order to improve one evaluation value by tuning a plurality of design variables. As an example of the design of the material product, in a case where a certain material is produced by mixing a plurality of compositions, the design assistance device 10 is used for tuning the design parameter group, in which one evaluation value is improved, with the design parameter group such as a compounding amount of each composition as a design variable and the evaluation value calculated on the basis of the plurality of measurement values measured relevant to the produced material as an object variable.

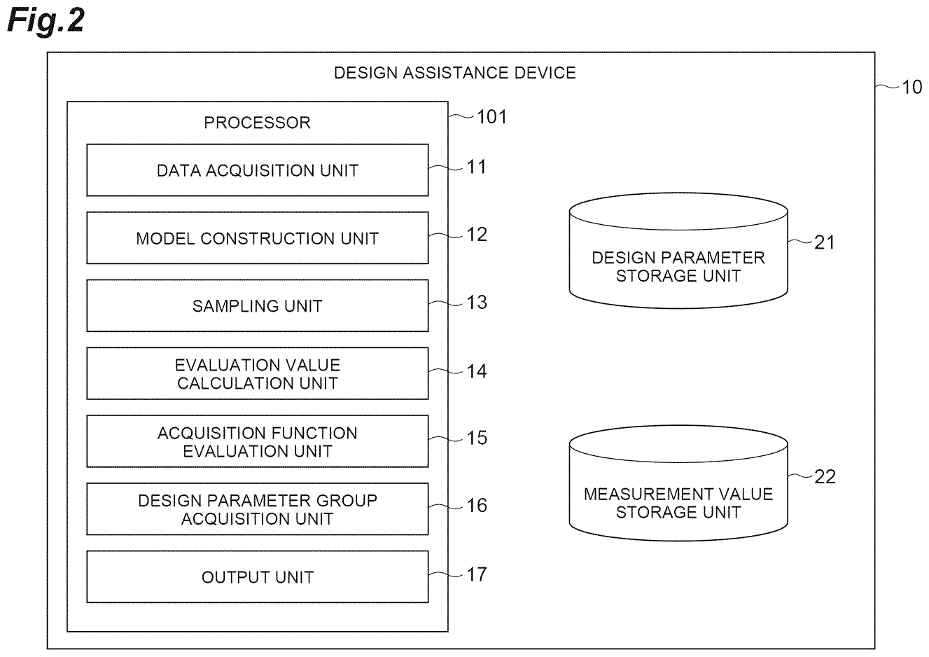

FIG. 2 is a block diagram illustrating an example of a function configuration of the design assistance device 10 according to the embodiment. The design assistance device 10 is a device obtaining a plurality of design parameters, in which one evaluation value indicating the characteristic of the material is improved, in the design of the material to be produced on the basis of the design parameter group consisting of the plurality of design parameters. As illustrated in FIG. 2, the design assistance device 10 may include function units configured in a processor 101, a design parameter storage unit 21, and a measurement value storage unit 22. Each function unit will be described below.

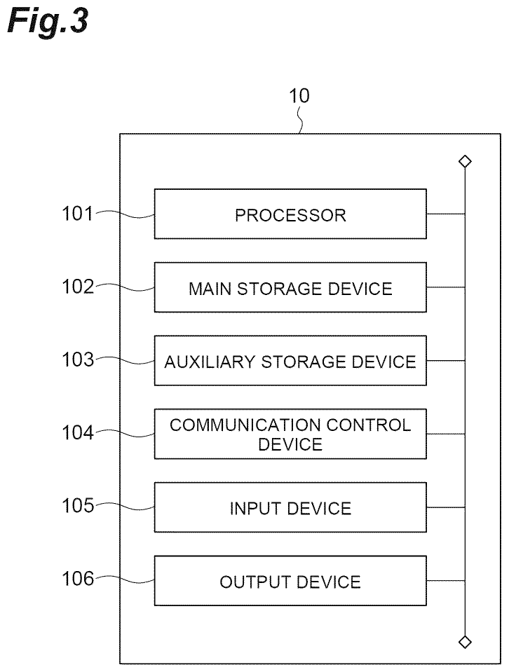

FIG. 3 is a diagram illustrating an example of a hardware configuration of a computer 100 configuring the design assistance device 10 according to the embodiment. Note that, the computer 100 may configure the design assistance device 10.

As an example, the computer 100 includes the processor 101, a main storage device 102, an auxiliary storage device 103, and a communication control device 104, as a hardware configuration element. The computer 100 configuring the design assistance device 10 may further include an input device 105 that is an input device, such as a keyboard, a touch panel, and a mouse, and an output device 106 such as a display.

The processor 101 is an arithmetic device executing an operating system and an application program. Examples of the processor include a central processing unit (CPU) and a graphics processing unit (GPU), but the type of processor 101 is not limited thereto. For example, the processor 101 may be a combination of a sensor and a dedicated circuit. The dedicated circuit may be a programmable circuit such as a field-programmable gate array (FPGA), or may be another type of circuit.

The main storage device 102 is a device storing a program for attaining the design assistance device 10 or the like, an arithmetic result output from the processor 101, and the like. The main storage device 102, for example, is composed of at least one of a read only memory (ROM) and a random access memory (RAM).

The auxiliary storage device 103, in general, is a device capable of storing a larger amount of data than the main storage device 102. The auxiliary storage device 103, for example, is composed of a non-volatile storage medium such as a hard disk and a flash memory. The auxiliary storage device 103 stores a design assistance program P1 for allowing the computer 100 to function as the design assistance device 10 or the like, and various data pieces.

The communication control device 104 is a device executing data communication with respect to another computer via a communication network. The communication control device 104, for example, is composed of a network card or a wireless communication module.

Each function element of the design assistance device 10 is attained by reading the corresponding program P1 on the processor 101 or the main storage device 102 and allowing the processor 101 to execute the program. The program P1 includes a code for attaining each function element of the corresponding server. The processor 101 operates the communication control device 104 in accordance with the program P1, and executes the reading and the writing of the data in the main storage device 102 or the auxiliary storage device 103. By such processing, each function element of the corresponding server is attained.

The program P1 may be provided after being permanently recorded in a tangible recording medium such as a CD-ROM, a DVD-ROM, and a semiconductor memory. Alternatively, at least one of such programs may be provided as a data signal superimposed on a carrier wave via a communication network.

Referring again to FIG. 2, the design assistance device 10 includes a data acquisition unit 11, a model construction unit 12, a sampling unit 13, an evaluation value calculation unit 14, an acquisition function evaluation unit 15, a design parameter group acquisition unit 16, and an output unit 17. The design parameter storage unit 21 and the measurement value storage unit 22, as illustrated in FIG. 2, may be configured in the design assistance device 10, or may be configured as another device accessible from the design assistance device 10.

The data acquisition unit 11 acquires a plurality of performance data pieces relevant to the produced material. The performance data consists of a pair of the design parameter group and the measurement value of each of the plurality of measurement items. The design parameter storage unit 21 is a storage unit storing the design parameter group in the performance data, and for example, may be configured in the main storage device 102, the auxiliary storage device 103, and the like. The measurement value storage unit 22 is a storage unit storing the measurement value in the performance data.

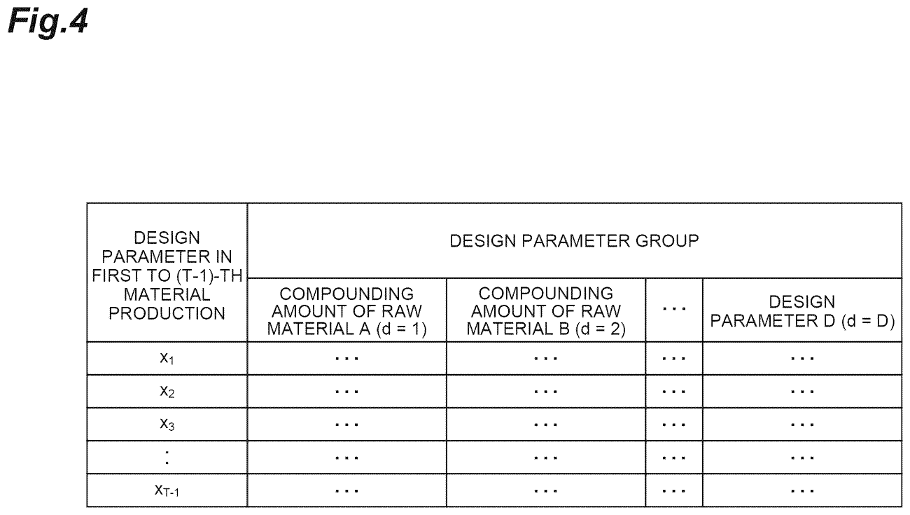

FIG. 4 is a diagram illustrating an example of the design parameter group stored in the design parameter storage unit 21. As illustrated in FIG. 4, the design parameter storage unit 21 stores a design parameter group xₜ in the first (t=1) to (T−1)-th (t=T−1) material production. The design parameter group x, as an example, may include the compounding amount of a raw material A, the compounding amount of a raw material B, a design parameter D, and the like, and may configure vector data of a dimension number according to the number of design parameters D. The design parameter, for example, may be non-vector data such as a molecular structure and an image, and the like, in addition to the exemplified design parameter. In addition, in the case of handling a problem of selecting the optimum molecule from a plurality of types of molecules, the design parameter may be data indicating options of the plurality of molecules.

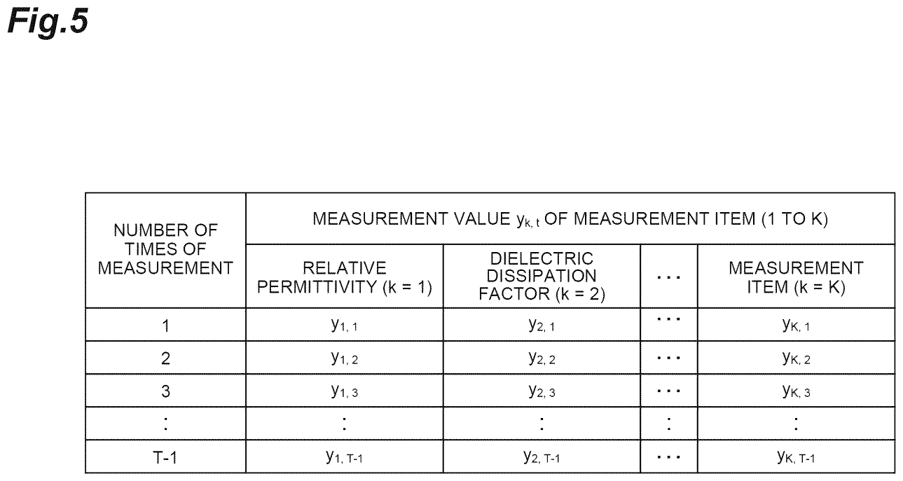

FIG. 5 is a diagram illustrating an example of the measurement value y stored in the measurement value storage unit 22. As illustrated in FIG. 5, the measurement value storage unit 22 stores measurement values y_{k, t} of a plurality of measurement items k (k=1 to K) indicating the characteristic of the produced material in the first (t=1) to (T−1)-th (t=T−1) material production. The measurement item k, as an example, may include a relative permittivity, a dielectric dissipation factor, and a measurement item K. A pair of the design parameter group xₜ and the measurement value y_{k, t} configure the performance data.

The design assistance device 10 obtains the T-th design parameter group x_{T}, in which one evaluation value calculated on the basis of the measurement value of each measurement item is improved, on the basis of the performance data in the first (t=1) to (T−1)-th (t=T−1) material production.

The model construction unit 12 constructs a predictive model on the basis of the performance data. The predictive model is a model for predicting a measurement value yₖ of the measurement item k as an object variable, as a probability distribution or an approximate or alternative index thereof, on the basis of the design parameter group x. The type of model configuring the predictive model is not limited insofar as the measurement value yₖ can be predicted as the probability distribution or the approximate or alternative index thereof.

For example, the predictive model may be a regression model having the design parameter x as input and the probability distribution of the measurement value yₖ as output. In a case where the predictive model is the regression model, the predictive model, for example, may be composed of any one of regression models such as linear regression, PLS regression, Gaussian process regression, random forest, and a neural network. The model construction unit 12 may configure the predictive model by a known machine learning method using the performance data. The model construction unit 12 may construct the predictive model by a machine learning method for applying the performance data to the predictive model to update the parameter of the predictive model.

The probability distribution obtained from the predictive model is not limited to a specific probability distribution such as Gaussian distribution, and may be a probability distribution according to the characteristic of the measurement item, and for example, may be a beta distribution and a discrete probability distribution.

In the predictive model constructed as the Gaussian process regression, the probability distribution of the measurement value is predicted by inputting the design parameter group x in the performance data configuring an explanatory variable of training data, the measurement value y configuring an object variable, and the design parameter x of a prediction target to the model.

In addition, the predictive model may be a machine learning model for predicting the probability distribution of the measurement value or the approximate or alternative index thereof by using any one of a posterior distribution of a prediction value based on Bayesian theory, a distribution of a prediction value of a predictor configuring an ensemble, a theoretical formula of a prediction interval and a confidence interval of a regression model, a distribution obtained by Monte Carlo dropout, and a distribution of the predictions of a plurality of predictors constructed in different conditions.

The prediction of the probability distribution of the measurement value, or the alternative index thereof can be obtained by a model-specific method. The probability distribution of the measurement value or the approximate or alternative index thereof can be obtained on the basis of the posterior distribution of the prediction value in the case of Gaussian process regression and a Bayesian neural network, on the basis of the distribution of the prediction of the predictor configuring the ensemble in the case of random forest, on the basis of the prediction interval and the confidence interval in the case of linear regression, and on the basis of the Monte Carlo dropout in the case of a neural network. Here, a method for calculating a distribution of the measurement value with respect to each machine learning model or an alternative index thereof is not limited to the method described above.

In addition, any model can also be extended to a model capable of predicting the probability distribution of the measurement value or the alternative index thereof. For example, a model using a distribution of a prediction value of each model, which is obtained by constructing a plurality of data sets by a bootstrap method or the like, and constructing a predictive model with respect to each data set, as the alternative index of the probability distribution of the measurement value can be used as an example. However, a method for extending the machine learning model to the model capable of predicting the probability distribution of the measurement value or the alternative index thereof is not limited to the method described above.

In addition, the model construction unit 12 may tune the hyperparameter of the predictive model by a known hyperparameter tuning method. That is, the model construction unit 12 may update the hyperparameter of the predictive model by maximum likelihood estimation using a vector representing the design parameter group x that is the explanatory variable in the performance data, and the measurement value y that is the object variable.

In addition, the predictive model may be constructed with a classification model. In a case where the predictive model is the classification model, the model construction unit 12 may construct the predictive model by a machine learning method in which a known probability distribution can be evaluated using the performance data.

As described above, by the model construction unit 12 constructing the predictive model with a predetermined regression model or classification model, it is possible to acquire the probability distribution of the measurement value of the measurement item, on the basis of any design parameter group x.

In addition, the predictive model may be a single task model for predicting the measurement value of one measurement item as the probability distribution or the approximate or alternative index thereof, or a multitask model for predicting the measurement values of the plurality of measurement items as the probability distribution or the approximate or alternative index thereof. As described above, by constructing the predictive model with a suitably configured multitask model or single task model in accordance with the property of the measurement item, it is possible to improve the prediction accuracy of the measurement value by the predictive model.

The sampling unit 13 samples a predetermined number of points of the measurement value group, with a plurality of measurement value groups sampled from a multidimensional probability distribution of the measurement value obtained from each predictive model as one sampling point.

Specifically, for example, in a case where the measurement values yₖ (k=1 to K) are in accordance with a multivariate normal distribution on the basis of the predictive model and are not correlated to each other, the measurement values are expressed as follows.

yₖ to N(mₖ(x), σₖ(x)²)

In such a case, the sampling unit 13 samples a plurality of measurement values yₖ (k=1 to K) from the probability distribution of the measurement value yₖ that is the object variable in the predictive model, on the basis of one design parameter group x.

More specifically, the sampling unit 13 samples each measurement value group yₖ, n (k=1 to K, n=1 to N) as the n-th (n: 1 to N) sampling point. A measurement value group yₙ of the n-th sampling point, as expressed below, configures a vector having the number of measurement values included in the measurement value group as a dimension number and each measurement value as an element.

$${y}_{n} = [ {y}_{1 , n} , {y}_{2 , n} , … , {y}_{k , n} , … , {y}_{K , n} ]$$

Then, the sampling unit 13 acquires a measurement value group set Y corresponding to N sampling points, which is the predetermined number of points.

$$Y = [ {y}_{1} , {y}_{2} , … , {y}_{n} , … , {y}_{N} ]$$

Measurement value groups y₁, y₂, . . . , yₙ, . . . , y_{N} each configure the vector.

Note that, in the above example, it is assumed that the measurement values yₖ as the object variable in the predictive model are in accordance with the normal distribution and are not correlated to each other, but the measurement values may be correlated to each other, and are not limited to the normal distribution, and may be in accordance with another probability distribution.

In addition, in a case where the measurement value sampled by using the predictive model of the measurement item is not included in a given domain of definition relevant to the measurement item, the sampling unit 13 may substitute the sampled measurement value with a predetermined value set in advance for the measurement item. Specifically, for example, in a case where a certain measurement item is a physical property value that is not capable of being a negative value, there is a possibility that the sampled measurement value is a negative value due to the sampling from the probability distribution based on the predictive model. In such a case, the sampling unit 13 substitutes the sampled negative measurement value with the predetermined value “0” set in advance for the measurement item. By including the predetermined value substituted as described above in the measurement value group, the accuracy of the evaluation value calculated later is improved.

In addition, the sampling by the sampling unit 13 has been described by an example of performing the sampling for each measurement item, but is not limited to such an example, and the sampling unit 13, for example, may collectively sample the measurement value group on the basis of the multivariate normal distribution defined by the predictive model of each measurement item.

In addition, the sampling unit 13 may obtain a sample of the measurement value group y_{k, n}, on the basis of a sampling point from a standard normal distribution sampled and stored in advance. Specifically, the sampling unit 13 samples in advance a sampling point y_std_{k, n} (n=1 to N) from the standard normal distribution that is a normal distribution with a mean 0 and a variance 1, and is capable of obtaining the sample of the measurement value group y_{k, n} by the following conversion formula.

$${y}_{k , n} = {y\_std}_{k , {n}^{*}} {σ}_{k} ( x ) + {m}_{k} ( x )$$

Note that, in the design assistance device 10 implemented on the computer, the sampling unit 13 may collectively perform the sampling at N sampling points, or may collectively perform the sampling corresponding to each of the plurality of design parameter groups x.

The evaluation value calculation unit 14 calculates the evaluation value of the measurement value group corresponding to one design parameter group x and one sampling point. Specifically, as described above, since the measurement value group of one sampling point configures the vector having the number of measurement values included in the measurement value group as the dimension number and each measurement value as the element, the evaluation value calculation unit 14 scalarizes the vector representing the measurement value group by predetermined arithmetic to calculate the evaluation value of each sampling point.

The evaluation value calculation unit 14 may calculate the evaluation value by a predetermined evaluation formula for performing predetermined arithmetic on the basis of the plurality of measurement values included in the measurement value group. The evaluation formula can be arbitrarily set, and for example, may be uniquely set in accordance with the industry to which the product or the like to be produced belongs, the business for producing the product or the like, and the business sector thereof, and the individual involved in the research and development of the product or the like.

The evaluation value calculation unit 14 may be a theoretical formula for calculating the characteristic value indicating the characteristic relevant to the product or the like. In a case where the evaluation value is the transmission loss of the electrical signal, the evaluation value calculation unit 14, as an example, calculates an evaluation value vₙ by Formula (1) described below.

$$Evaluation Value ( Transmission Loss ) {v}_{n} ∝ Frequency \times √ Relative Permittivity \times Dielectric Dissipation Factor \qquad ( 1 )$$

That is, the evaluation value vₙ is calculated as a scalar value obtained by multiplying the product of the frequency, the square root of the relative permittivity, and the dielectric dissipation factor by the coefficient.

The evaluation value calculation unit 14 is capable of obtaining an evaluation value set V consisting of the first to N-th evaluation values vₙ by calculating the evaluation value vₙ of each of the measurement value groups yₙ of the first to N-th sampling points.

$$V = [ {v}_{1} , {v}_{2} , … , {v}_{n} , … , {v}_{N} ]$$

As described above, the evaluation values v₁, v₂, . . . , vₙ, . . . , v_{N} each configure the scalar value.

Note that, in the design assistance device 10 implemented on the computer, the evaluation value calculation unit 14 may collectively perform the calculation of the evaluation values v₁, v₂, . . . , vₙ, . . . , v_{N} respectively corresponding to N sampling points.

The acquisition function evaluation unit 15 outputs an acquisition function evaluation value relevant to the improvement of the evaluation value by a predetermined acquisition function, with the design parameter group as input, on the basis of a distribution of the evaluation value of each sampling point.

The acquisition function evaluation unit 15, for example, may output the acquisition function evaluation value by using a known acquisition function such as lower confidence bound (LCB). LCB is used in the case of minimizing the output of the function, and a suitable design parameter group x is obtained by minimizing the value of LCB.

In a case where the acquisition function is constructed by LCB, the acquisition function evaluation unit 15 defines and constructs an acquisition function evaluation value A(x) as represented in Formula (2) described below.

$$A ( x ) = m v ( x ) - a σ v ( x ) \qquad ( 2 )$$

The acquisition function evaluation unit 15 evaluates and acquires a mean mv(x) and a standard deviation σv(x) on the basis of a distribution of the evaluation value vₙ included in the evaluation value set V, and outputs the acquisition function evaluation value by an acquisition function represented in Formula (2). In Formula (2), a is any parameter. Formula (2) of the acquisition function represents the lower limit of the confidence interval in the case of assuming that the measurement value of vₙ in the next experiment is in accordance with a normal distribution when the design parameter group x is set as a parameter.

In addition, the acquisition function evaluation unit 15 may output the acquisition function evaluation value A(x) by a known function such as upper confidence bound (UCB), expected improvement (EI), and probability of improvement (PI).

The design parameter group acquisition unit 16 acquires at least one design parameter group by the optimization of the acquisition function evaluation value A(x) output by the acquisition function evaluation unit 15.

As an example, the design parameter group acquisition unit 16 may acquire at least one design parameter group x for optimizing the output of the acquisition function. Specifically, the design parameter group acquisition unit 16 performs the optimization using the acquisition function evaluation value A(x) output by the acquisition function evaluation unit 15 as an object variable, and acquires the design parameter group x as an optimum solution.

In addition, as an example, the design parameter group acquisition unit 16 may acquire the plurality of design parameter groups by a predetermined algorithm. Specifically, the design parameter group acquisition unit 16 may acquire the plurality of design parameter groups by applying a batch Bayesian optimization method to the acquisition function. The batch Bayesian optimization method, for example, may be a method such as local penalization, but such a method is not limited.

The output unit 17 outputs the design parameter group acquired by the design parameter group acquisition unit 16. That is, the output unit 17 outputs the design parameter group obtained on the basis of the performance data in the first (t=1) to (T−1)-th (t=T−1) material production, as the design parameter group x_{T} for producing the T-th material.

In addition, in a case where the plurality of design parameter groups are acquired by the design parameter group acquisition unit 16, the output unit 17 outputs the acquired design parameter group as a design parameter group for material production for N times after the (T−1)-th material production. The design parameter group for the material production for a plurality of times may be used in the simultaneous experiments and material production.

The output mode is not limited, but the output unit 17, for example, outputs a design parameter group candidate by displaying the design parameter group candidate on a predetermined display device or storing the design parameter group candidate in a predetermined storage unit.

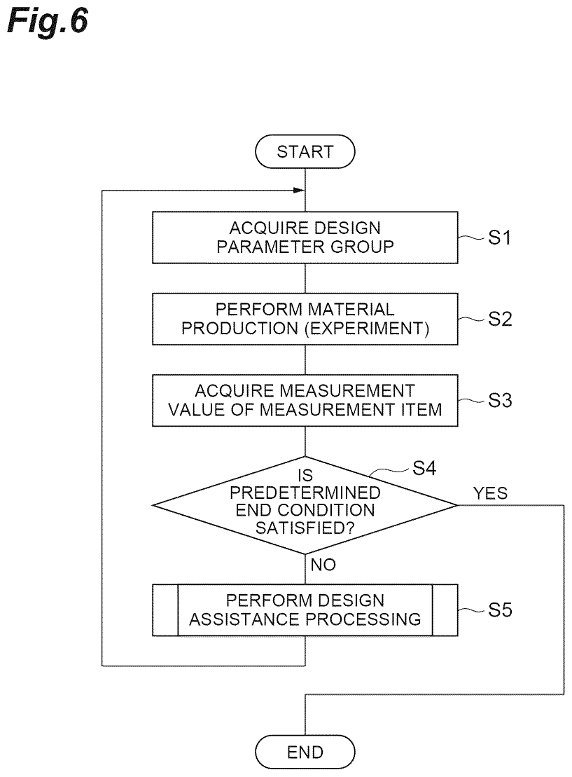

FIG. 6 is a flowchart illustrating an optimization process of the measurement item and the design parameter group in the material design.

In step S1, the design parameter group is acquired. Here, the design parameter group to be acquired is a design parameter group for the initial material production (experiment), and may be an arbitrarily set design parameter group, or may be a design parameter group set on the basis of an experiment or the like that has already been performed.

In step S2, the material production is performed. In step S3, the measurement value of the measurement item of the produced material is acquired. The pair of the design parameter group as a production condition in step S2 and the measurement value of each measurement item acquired in step S3 configure the performance data.

In step S4, whether a predetermined end condition is satisfied is determined. The predetermined end condition is a condition for the optimization of the design parameter group and the evaluation value, and may be arbitrarily set. The end condition for optimization, for example, may be reaching a predetermined number of times of the production (the experiment) and the acquisition of the measurement value, reaching a target value of the evaluation value, the convergence of the optimization, and the like. In a case where it is determined that the predetermined end condition is satisfied, the optimization process is ended. In a case where it is not determined that the predetermined end condition is satisfied, the process proceeds to step S5.

In step S5, the design assistance processing of the design assistance device 10 is performed. The design assistance processing is processing of outputting the design parameter group for the next material production. Then, the process returns again to step S1.

Note that, in the first cycle of a processing cycle composed of steps S1 to S5, in a case where a plurality of pairs of the design parameter group and the measurement value of the measurement item are obtained as the initial data, the processing of steps S1 to S4 is omitted. In a case where the initial data is not obtained, in step S1, for example, the design parameter group obtained by any method such as design of experiment and random search is acquired. In the second and subsequent cycles of the processing cycle, in step S1, the design parameter group output in step S5 is acquired.

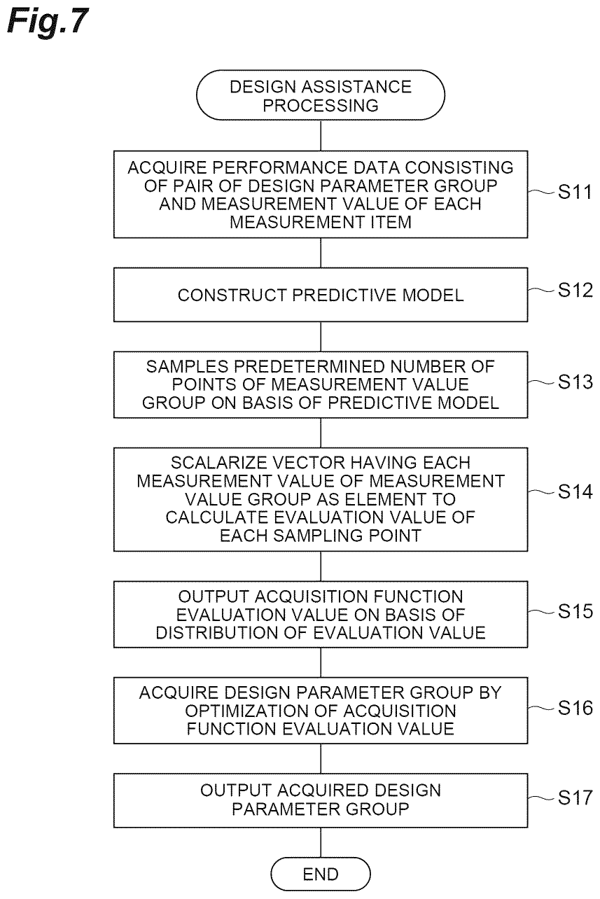

FIG. 7 is a flowchart illustrating an example of the contents of a design assistance method in the design assistance device 10 according to the embodiment, and illustrates the processing of step S5 in FIG. 6. The design assistance method is executed by reading the design assistance program P1 in the processor 101 and executing the program to attain each of the function units 11 to 17.

In step S11, the data acquisition unit 11 acquires the plurality of performance data pieces relevant to the produced material. The performance data consists of the pair of the design parameter group and the measurement value of each measurement item.

In step S12, the model construction unit 12 constructs the predictive model on the basis of the performance data.

In step S13, the sampling unit 13 samples the predetermined number of points of the measurement value group, with the plurality of measurement value groups sampled from the multidimensional probability distribution of the measurement value obtained from each predictive model on the basis of one design parameter group x as one sampling point, on the basis of the predictive model.

In step S14, the evaluation value calculation unit 14 scalarizes the vector having the measurement value of each measurement item of the measurement value group as the element by the predetermined arithmetic to calculate the evaluation value of each sampling point.

In step S15, the acquisition function evaluation unit 15 outputs the predetermined acquisition function evaluation value on the basis of the distribution of the evaluation value of each sampling point.

In step S16, the design parameter group acquisition unit 16 acquires at least one design parameter group by the optimization of the acquisition function evaluation value obtained by the acquisition function evaluation unit 15 in step S15.

In step S17, the output unit 17 outputs the design parameter group acquired by the design parameter group acquisition unit 16 in step S16 as the design parameter group for the next material production (step S1).

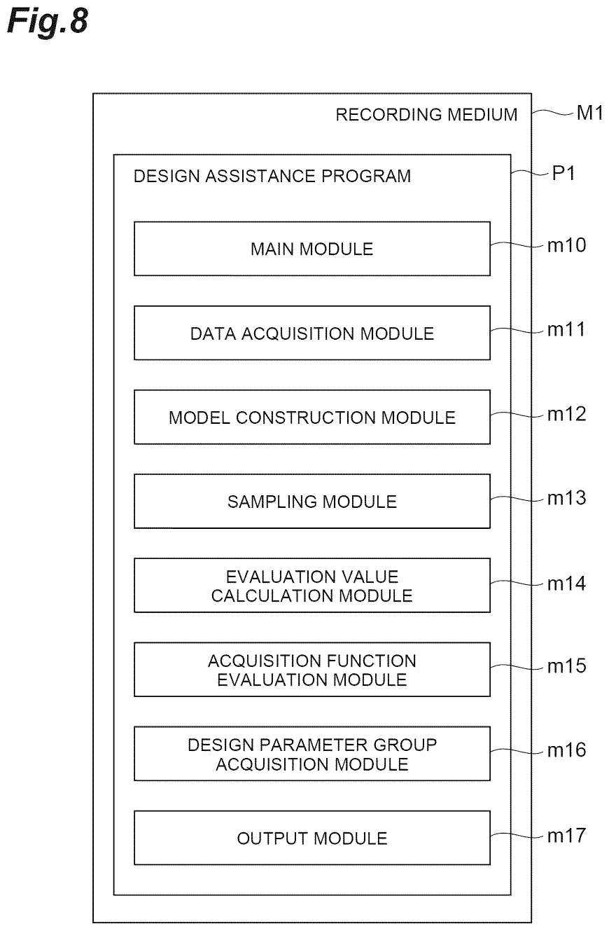

Next, a design assistance program for allowing the computer to function as the design assistance device 10 of this embodiment will be described. FIG. 8 is a diagram illustrating the configuration of the design assistance program.

The design assistance program P1 is configured by including a main module m10 comprehensively controlling the design assistance processing of the design assistance device 10, a data acquisition module m11, a model construction module m12, a sampling module m13, an evaluation value calculation module m14, an acquisition function evaluation module m15, a design parameter group acquisition module m16, and an output module m17. Then, by each of the modules m11 to m17, each function for the data acquisition unit 11, the model construction unit 12, the sampling unit 13, the evaluation value calculation unit 14, the acquisition function evaluation unit 15, the design parameter group acquisition unit 16, and the output unit 17 is attained.

Note that, the design assistance program P1 may be transmitted via a transmission medium such as a communication line, or as illustrated in FIG. 8, may be stored in a recording medium M1.

According to the design assistance device 10, the design assistance method, and the design assistance program P1 of this embodiment described above, the predictive model for predicting the measurement values of the plurality of measurement items for the calculation and the evaluation of the evaluation value is constructed for each measurement item on the basis of the performance data. Since such a predictive model predicts the measurement value of the measurement item as the probability distribution or the approximate or alternative index thereof, it is possible to sample any number of points of the measurement value group, on the basis of the multidimensional distribution of the measurement value obtained from the predictive model of each measurement item. By performing the arithmetic according to the predetermined evaluation formula with respect to the vector having the measurement value group of each sampling point as the element, it is possible to obtain the evaluation value relevant to each sampling point expressed by the scalar value. Then, by optimizing the acquisition function evaluation value output using the predetermined acquisition function, on the basis of the distribution of the evaluation value of each sampling point, it is possible to obtain the design parameter group suitable for the next experiment or the like. Accordingly, it is possible to obtain a more accurate predictive model relevant to the measurement value, compared to a method for constructing the acquisition function by directly learning the evaluation value, and it is possible to reduce the number of experiments since the suitability of the design parameter group to be adopted to the experiment or the like is improved by optimizing the acquisition function evaluation value relevant to the evaluation value of the measurement value group obtained by the predictive model.

The present invention has been described in detail on the basis of the embodiment. However, the present invention is not limited to the embodiment described above. The present invention can be variously modified within a range not departing from the gist thereof.

### REFERENCE SIGNS LIST

P1: design assistance program, m10: main module, m11: data acquisition module, m12: model construction module, m13: sampling module, m14: evaluation value calculation module, m15: acquisition function evaluation module, m16: design parameter group acquisition module, m17: output module, 10: design assistance device, 11: data acquisition unit, 12: model construction unit, 13: sampling unit, 14: evaluation value calculation unit, 15: acquisition function evaluation unit, 16: design parameter group acquisition unit, 17: output unit, 21: design parameter storage unit, 22: measurement value storage unit.

1. A design assistance device obtaining a plurality of design parameters, in which one evaluation value indicating a characteristic of a product, an in-progress product, a half-finished product, a component, or a production prototype is improved, in order to be applied to a method for optimizing a design parameter by repeating determination of the design parameter and production of the product, the in-progress product, the half-finished product, the component, or the production prototype based on the determined design parameter, in design of the product, the in-progress product, the half-finished product, the component, or the production prototype to be produced on the basis of a design parameter group consisting of the plurality of design parameters,
the one evaluation value being calculated on the basis of measurement values of a plurality of measurement items,
the design assistance device, comprising:
a data acquisition unit acquiring a plurality of performance data pieces consisting of the design parameter group and the measurement value of each of the plurality of measurement items, relevant to the produced product, in-progress product, half-finished product, component, or production prototype;
a model construction unit constructing, on the basis of the performance data, a predictive model for predicting the measurement value of the measurement item as a probability distribution or an approximate or alternative index thereof on the basis of the design parameter group;
a sampling unit sampling a predetermined number of points of a measurement value group, with the measurement value group consisting of a plurality of measurement values sampled from a multidimensional probability distribution of the measurement value obtained from each predictive model as one sampling point;
an evaluation value calculation unit scalarizing a vector having the number of measurement values included in the measurement value group as a dimension number and a value of each measurement value as an element by predetermined arithmetic to calculate an evaluation value of the measurement value group of each sampling point;
an acquisition function evaluation unit outputting an acquisition function evaluation value relevant to the improvement of the evaluation value by a predetermined acquisition function, with the design parameter group as input, on the basis of a distribution of the evaluation value of each sampling point;
a design parameter group acquisition unit acquiring at least one design parameter group by optimization of the acquisition function evaluation value; and
an output unit outputting the design parameter group acquired by the design parameter group acquisition unit.

2. The design assistance device according to claim 1,
wherein the evaluation value calculation unit calculates the evaluation value by a predetermined evaluation formula for performing predetermined arithmetic on the basis of the plurality of measurement values included in the measurement value group.

3. The design assistance device according to claim 1,
wherein the evaluation value calculation unit calculates a characteristic value as the evaluation value by a theoretical formula for calculating the characteristic value indicating the characteristic relevant to the product, the in-progress product, the half-finished product, the component, or the production prototype, on the basis of the plurality of measurement values included in the measurement value group.

4. The design assistance device according to claim 1,
wherein when the measurement value sampled by using the predictive model of the measurement item is not included in a given domain of definition relevant to the measurement item, the sampling unit substitutes the sampled measurement value with a predetermined value set in advance for the measurement item.

5. The design assistance device according to claim 1,
wherein the acquisition function evaluation unit outputs the acquisition function evaluation value by any acquisition function of lower confidence bound (LCB), upper confidence bound (UCB), expected improvement (EI), and probability of improvement (PI).

6. The design assistance device according to claim 1,
wherein the design parameter group acquisition unit acquires one design parameter group for optimizing the acquisition function evaluation value.

7. The design assistance device according to claim 1,
wherein the design parameter group acquisition unit acquires a plurality of the design parameter groups by a predetermined algorithm.

8. The design assistance device according to claim 1,
wherein the predictive model is a regression model or a classification model having the design parameter group as input and the probability distribution of the measurement value as output, and
the model construction unit constructs the predictive model by machine learning using the performance data.

9. The design assistance device according to claim 8,
wherein the predictive model is a machine learning model for predicting the probability distribution of the measurement value or the approximate or alternative index thereof by using any one of a posterior distribution of a prediction value based on Bayesian theory, a distribution of a prediction value of a predictor configuring an ensemble, a theoretical formula of a prediction interval and a confidence interval of a regression model, Monte Carlo dropout, and a distribution of predictions of a plurality of predictors constructed in different conditions.

10. A design assistance method of a design assistance device obtaining a plurality of design parameters, in which one evaluation value indicating a characteristic of a product, an in-progress product, a half-finished product, a component, or a production prototype is improved, in order to be applied to a method for optimizing a design parameter by repeating determination of the design parameter and production of the product, the in-progress product, the half-finished product, the component, or the production prototype based on the determined design parameter, in design of the product, the in-progress product, the half-finished product, the component, or the production prototype to be produced on the basis of a design parameter group consisting of the plurality of design parameters,
the one evaluation value being calculated on the basis of measurement values of a plurality of measurement items,
the design assistance method, comprising:
a data acquisition step of acquiring a plurality of performance data pieces consisting of the design parameter group and the measurement value of each of the plurality of measurement items, relevant to the produced product, in-progress product, half-finished product, component, or production prototype;
a model construction step of constructing, on the basis of the performance data, a predictive model for predicting the measurement value of the measurement item as a probability distribution or an approximate or alternative index thereof on the basis of the design parameter group;
a sampling step of sampling a predetermined number of points of a measurement value group, with the measurement value group consisting of a plurality of measurement values sampled from a multidimensional probability distribution of the measurement value obtained from each predictive model as one sampling point;
an evaluation value calculation step of scalarizing a vector having the number of measurement values included in the measurement value group as a dimension number and a value of each measurement value as an element by predetermined arithmetic to calculate an evaluation value of the measurement value group of each sampling point;
an acquisition function evaluation step of outputting an acquisition function evaluation value relevant to the improvement of the evaluation value by a predetermined acquisition function, with the design parameter group as input, on the basis of a distribution of the evaluation value of each sampling point;
a design parameter group acquisition step of acquiring at least one design parameter group by optimization of the acquisition function evaluation value; and
an output step of outputting the design parameter group acquired in the design parameter group acquisition step.

11. A non-transitory computer-readable recording medium storing a design assistance program for allowing a computer to function as a design assistance device obtaining a plurality of design parameters, in which one evaluation value indicating a characteristic of a product, an in-progress product, a half-finished product, a component, or a production prototype is improved, in order to be applied to a method for optimizing a design parameter by repeating determination of the design parameter and production of the product, the in-progress product, the half-finished product, the component, or the production prototype based on the determined design parameter, in design of the product, the in-progress product, the half-finished product, the component, or the production prototype to be produced on the basis of a design parameter group consisting of the plurality of design parameters,
the one evaluation value being calculated on the basis of measurement values of a plurality of measurement items,
the design assistance program, attaining:
a data acquisition function of acquiring a plurality of performance data pieces consisting of the design parameter group and the measurement value of each of the plurality of measurement items, relevant to the produced product, in-progress product, half-finished product, component, or production prototype;
a model construction function of constructing, on the basis of the performance data, a predictive model for predicting the measurement value of the measurement item as a probability distribution or an approximate or alternative index thereof on the basis of the design parameter group;
a sampling function of sampling a predetermined number of points of a measurement value group, with the measurement value group consisting of a plurality of measurement values sampled from a multidimensional probability distribution of the measurement value obtained from each predictive model as one sampling point;
an evaluation value calculation function of scalarizing a vector having the number of measurement values included in the measurement value group as a dimension number and a value of each measurement value as an element by predetermined arithmetic to calculate an evaluation value of the measurement value group of each sampling point;
an acquisition function evaluation function of outputting an acquisition function evaluation value relevant to the improvement of the evaluation value by a predetermined acquisition function, with the design parameter group as input, on the basis of a distribution of the evaluation value of each sampling point;
a design parameter group acquisition function of acquiring at least one design parameter group by optimization of the acquisition function evaluation value; and
an output function of outputting the design parameter group acquired by the design parameter group acquisition function.
